(19) United States
(12) Patent Application Publication
(10) Pub. No.: US 2025/0328081 A1
(43) Pub. Date: Oct. 23, 2025

(54) UNDERLAYER WITH BONDED DOPANTS FOR PHOTOLITHOGRAPHY

(71) Applicant: Lam Research Corporation, Fremont, CA (US)

(72) Inventors: Siva Krishnan KANAKASABAPATHY, Pleasanton, CA (US); Bhadri VARADARAJAN, Beaverton, OR (US); Arpan Pravin MAHOROWALA, West Linn, OR (US); Durgalakshmi A SINGHAL, Portland, OR (US)

(21) Appl. No.: 18/868,349

(22) PCT Filed: May 8, 2023
(86) PCT No.: PCT/US2023/066718

§ 371 Date: Nov. 22, 2024

Related U.S. Application Data
(60) Provisional application No. 63/365,239, filed on May 24, 2022.

(51) Int. Cl. G03F 7/00; G03F 7/004; H01J 37/32

(52) U.S. Cl. CPC G03F 7/70033; G03F 7/0043; G03F 7/70858; H01J 37/32357

(57) ABSTRACT

Examples are disclosed that relate to use of extreme ultraviolet (EUV)-absorbing photoelectron-emissive dopants that are bonded to atoms in a hydrogen-contributing photosensitive underlayer for a photoresist. One example provides a method of forming a hydrogen-contributing photosensitive underlayer on a substrate. The method comprises exposing the substrate to a dopant precursor and a hydrocarbon precursor, the dopant precursor comprising an extreme ultraviolet (EUV)-absorbing photoelectron-emissive dopant bonded within a carbon-containing polymerizable molecule. The method further comprises exposing the substrate to a radical species formed by a plasma. The method further comprises forming the hydrogen-contributing photosensitive underlayer on the substrate from the dopant precursor and the hydrocarbon precursor by reaction of the dopant precursor and the hydrocarbon precursor with the radical species.

### BACKGROUND

In photolithography, a photoresist is used to transfer a pattern of light onto a substrate and form a patterned coating. First, a layer of a light-sensitive photoresist material is applied on a substrate. Then, using a patterning mask, unmasked regions of the photoresist are exposed to light. Exposure may either strengthen a negative photoresist or degrade a positive photoresist. Next, a developer is used to remove masked regions of a negative photoresist, or degraded regions of a positive photoresist. The remaining photoresist material forms the patterned coating on the substrate. The patterned coating can be used to selectively protect coated regions of the substrate from a subsequent deposition or etching process, for example.

### SUMMARY

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter. Furthermore, the claimed subject matter is not limited to implementations that solve any or all disadvantages noted in any part of this disclosure.

Examples are disclosed that relate to use of extreme ultraviolet (EUV)-absorbing photoelectron-emissive dopants that are bonded to atoms in a hydrogen-contributing photosensitive underlayer for a photoresist.

One example provides a method of forming a photosensitive underlayer on a substrate. The method comprises exposing the substrate to a dopant precursor and a hydrocarbon precursor, the dopant precursor comprising an extreme ultraviolet (EUV)-absorbing photoelectron-emissive dopant bonded within a carbon-containing polymerizable molecule. The method further comprises exposing the substrate to a radical species. The method further comprises forming a hydrogen-contributing photosensitive underlayer on the substrate from the dopant precursor and the hydrocarbon precursor by reaction of the dopant precursor and the hydrocarbon precursor with the radical species.

In some such examples, exposing the substrate to the radical species comprises introducing the radical species from a remote plasma into a processing chamber comprising the substrate through an ion-shielding and radiation-shielding inlet.

In some such examples, the dopant precursor additionally or alternatively is introduced downstream of an ion-shielding and radiation-shielding structure of the ion-shielding and radiation-shielding inlet.

In some such examples, the carbon-containing polymerizable molecule additionally or alternatively comprises one or more of a carbon-carbon double bond, a carbon-carbon triple bond, or a cyclic group.

In some such examples, the method additionally or alternatively further comprises mixing the hydrocarbon precursor with hydrogen-containing gas before exposing the substrate to the hydrocarbon precursor.

In some such examples, the dopant precursor additionally or alternatively comprises an iodine-containing dopant precursor.

In some such examples, the iodine-containing dopant precursor additionally or alternatively comprises one or more of iodoethyne or 3-iodopropene.

In some such examples, the dopant precursor additionally or alternatively comprises a tin-containing dopant precursor.

In some such examples, the tin-containing dopant precursor additionally or alternatively comprises one or more of dimethyl tin(II), diethyl tin(II), tetravinyl tin(IV) or dimethyl(divinyl)tin(IV).

In some such examples, a ratio of hydrocarbon precursor gas flow in standard cubic centimeters per minute (sccm) to dopant precursor gas flow in sccm additionally or alternatively is within a range of 2:1 to 100:1.

In some such examples, the method additionally or alternatively further comprises controlling a substrate heater to heat to a temperature within a range of 100° C. to 300° C.

Another example provides a patterning stack disposed on a substrate. The patterning stack comprises a photoresist layer. The patterning stack further comprises a hydrogen-contributing photosensitive underlayer disposed between the photoresist layer and the substrate. The hydrogen-contributing photosensitive underlayer comprises extreme ultraviolet (EUV)-absorbing photoelectron-emissive dopants bonded to atoms in the hydrogen-contributing photosensitive underlayer.

In some such examples, the hydrogen-contributing photosensitive underlayer comprises silicon carbide.

In some such examples, the hydrogen-contributing photosensitive underlayer additionally or alternatively comprises a polymer.

In some such examples, the EUV-absorbing photoelectron-emissive dopant additionally or alternatively comprises one or more of In, Sn, Sb, Te, or I.

In some such examples, the photoresist layer additionally or alternatively comprises an extreme ultraviolet (EUV) photoresist.

In some such examples, the EUV photoresist additionally or alternatively comprise a tin-based metal oxide photoresist.

Another example provides a processing tool. The processing tool comprises a processing chamber. The processing tool further comprises a plasma generator. The processing tool further comprises a radiofrequency power source configured to provide radiofrequency power to the plasma generator. The processing tool further comprises flow control hardware configured to control gas flow into the processing chamber and into the plasma generator. The processing tool further comprises a logic subsystem and a storage subsystem comprising instructions executable by the logic subsystem to control the flow control hardware to introduce a dopant precursor and a hydrocarbon precursor into the processing chamber, the dopant precursor comprising an extreme ultraviolet (EUV)-absorbing photoelectron-emissive dopant bonded within a carbon-containing polymerizable molecule. The instructions are further executable to control the flow control hardware to introduce an inert gas into the plasma generator. The instructions are further executable to control the radiofrequency power source to form a plasma in the plasma generator. The instructions are further executable to control the flow control hardware to introduce a radical species precursor into the plasma generator.

In some such examples, the processing tool further comprises a dopant precursor gas source, wherein the dopant precursor gas source comprises one or more of an iodine-containing dopant precursor or a tin-containing dopant precursor.

In some such examples, the processing tool additionally or alternatively further comprises an ion-shielding and radiation-shielding inlet connecting the plasma generator and the processing chamber.

In some such examples, the instructions are additionally or alternatively executable to control the flow control hardware to flow the hydrocarbon precursor and flow the dopant precursor with a gas flow ratio within a range of 2 sccm:1 sccm to 10 sccm:1 sccm.

In some such examples, the processing tool additionally or alternatively further comprises a substrate heater, and the instructions are further executable to control the substrate heater to heat to a temperature within a range of 100° C. to 300° C.

### BRIEF DESCRIPTION OF THE DRAWINGS

FIGS. 1A-1B schematically illustrate dopant hydride formation in a hydrogen-contributing photosensitive underlayer comprising loose EUV-absorbing photoelectron-emissive dopants.

FIGS. 2A-2C schematically illustrate chemical changes that occur in a patterning stack at various processing stages in an example extreme ultraviolet (EUV) photolithography process.

FIGS. 3A-3D schematically illustrate chemical reactions that may occur in an example tin-based metal oxide EUV photoresist layer in an example EUV photolithography process.

FIG. 4 schematically illustrates migration of labile hydrogen in a hydrogen-contributing photosensitive underlayer comprising bonded EUV-absorbing photoelectron-emissive dopants.

FIG. 5 schematically illustrates an example processing tool that can be used to form a hydrogen-contributing photosensitive underlayer comprising EUV-absorbing photoelectron-emissive dopants bonded to carbon atoms.

FIG. 6 schematically illustrates an example reaction of a dopant precursor with a hydrocarbon precursor to form a hydrogen-contributing photosensitive underlayer comprising bonded EUV-absorbing photoelectron-emissive dopants.

FIG. 7 schematically illustrates another example reaction of a dopant precursor with a hydrocarbon precursor to form a hydrogen-contributing photosensitive underlayer comprising bonded EUV-absorbing photoelectron-emissive dopants.

FIG. 8 shows a flow diagram illustrating an example method for forming a patterning stack.

FIG. 9 shows a block diagram of an example computing system.

### DETAILED DESCRIPTION

The term “aliphatic” may generally represent organic compounds lacking aromatic groups. The term “aliphatic ligand” may generally represent a ligand derived from an aliphatic where one hydrogen atom is removed to allow the ligand to bond to a dopant atom.

The term “alkane” may generally represent compounds comprising a general formula CₙH₂ₙ₊₂, and also substituted linear alkanes. Example alkanes include methane, ethane, propane, and butane. The term “alkyl” may generally represent a functional group comprising a general formula CₙH₂ₙ₊₁ which results from the removal of one hydrogen from an alkane. Example alkyl groups include methyl, ethyl, propyl, and butyl. Example alkyls that may be suitable for use as an aliphatic ligand as disclosed herein may comprise alkyls in which n=1 to 12.

The term “alkene” may generally represent hydrocarbon compounds comprising at least one carbon-carbon double bond. Alkenes comprising one carbon-carbon double bond have a general formula of CₙH₂ₙ. Example alkenes include ethene, propene, and butene. Alkenes may have more than one carbon-carbon double bond, such as dienes, allenes, and cumulenes. The term “alkenyl” may generally represent a functional group comprising a general formula CₙH₂ₙ₋₁ which results from the removal of one hydrogen from an alkene. Example alkenyls include vinyl, allyl, propenyl, and butenyl. Example alkenyls that may be suitable for use as an unsaturated aliphatic ligand in a dopant precursor as disclosed herein may comprise alkenyls in which n=2 to 12.

The term “alkyne” may generally represent hydrocarbon compounds comprising at least one carbon-carbon triple bond. Alkynes comprising one carbon-carbon triple bond have a general formula of CₙH₂ₙ₋₂. Alkynes may have more than one carbon-carbon triple bond, such as diynes, which have two carbon-carbon triple bonds. The term “alkynyl” may generally represent a functional group comprising a general formula CₙH₂ₙ₋₃ which results from the removal of one hydrogen from an alkyne. Example alkynyls include acetylenyl, propynyl, and butynyl. Example alkynyls that may be suitable for use as an unsaturated aliphatic ligand in a dopant precursor as disclosed herein may comprise alkynyls in which n=2 to 12.

The term “aromatic” represents a planar cyclic compound comprising pi bonding in resonance. The term “aromatic” comprises homocyclic compounds in which all atoms in a ring structure are carbon, and also heterocyclics in which one or more atoms in a ring structure are elements other than carbon (e.g. nitrogen).

The term “carbon-containing polymerizable molecule” may generally represent aliphatic molecules and aromatic molecules that are capable of bonding an extreme ultraviolet (EUV)-absorbing photoelectron-emissive dopant, and that are capable of polymerization with a hydrocarbon precursor as disclosed herein. Examples of carbon-containing polymerizable molecules include molecules with carbon-carbon double bonds, molecules with carbon-carbon triple bonds, molecules with cyclic groups, and molecules with aromatic groups.

The term “chemical vapor deposition” may generally represent a process in which a substrate is exposed to one or more gas phase precursors which react to form a deposited film on the substrate surface.

The term “cyclic hydrocarbon” may generally represent saturated and unsaturated hydrocarbon molecules comprising a closed ring structure. A cyclic hydrocarbon can be aliphatic or aromatic. Example cyclic hydrocarbons include cyclopropane and cyclobutene. The term “cycloalkyl” may generally represent a functional group which results from the removal of one hydrogen from a cycloalkane. Example cycloalkyls that may be suitable for use as a carbon-containing polymerizable ligand in a dopant precursor as disclosed herein include cyclopropyl, cyclobutyl, and cyclohexyl. The term “cycloalkenyl” may generally represent a functional group which results from the removal of one hydrogen from a cycloalkene. Example cycloalkenyls that may be suitable for use as an aliphatic ligand in a dopant precursor as disclosed herein include cyclobutenyl and cyclohexenyl. The term “cyclic group” may generally represent a functional group comprising a cyclic hydrocarbon.

The term “dopant precursor” may generally represent any suitable compound comprising a EUV-absorbing photoelectron-emissive dopant that is bonded within a carbon-containing polymerizable molecule that may react with a hydrocarbon precursor to form a hydrogen-contributing photosensitive underlayer. Example EUV-absorbing photoelectron-emissive dopants suitable for use in a hydrogen-contributing photosensitive underlayer include indium (In), tin(Sn), antimony (Sb), tellurium (Te), and iodine (I). The dopant precursor may have the general formula Z—Rₙ, n≥1, where Z is any suitable EUV-absorbing element which emits EUV photoelectrons, and where R generally represents a ligand, one or more of which comprises a carbon-containing molecule. Each R may independently be, for example, hydrogen, an alkyl, substituted alkyl, cycloalkyl, substituted cycloalkyl, alkenyl, substituted alkenyl, alkynyl, substituted alkynyl, cycloalkenyl, or substituted cycloalkenyl. Suitable alkyl ligands include methyl, ethyl, propyl, and t-butyl. Suitable substituted alkyls include iodoethyl and aminopropyl. Suitable cycloalkyl ligands include cyclopropyl and cyclobutyl groups. Suitable substituted cycloalkyl ligands include aminocyclohexyl. Suitable alkenyl ligands include vinyl (ethenyl), allyl, propenyl, and 3-butenyl. Suitable substituted alkenyl ligands include aminovinyl. Suitable alkynyl ligands include ethynyl and propynyl. Suitable substituted alkynyl ligands include chloropropynyl. Suitable cycloalkenyl ligands include cyclobutenyl and cyclohexenyl.

Example dopant precursors that may be suitable for forming a hydrogen-contributing photosensitive underlayer include organoantimony compounds (e.g. Sb(V) compounds having the general formula R₅Sb and Sb(III) compounds having the general formula R₃Sb), organotin compounds (e.g. Sn(IV) compounds having the general formula R₄Sn), organotellurium compounds (e.g. telluride compounds having the general formula R₂Te or (RTe)₂, Te(IV) compounds having the general formula R₄Te, and telluroxides having the general formula R₂TeO), and organoiodine compounds of a general formula R-I. Example dopant precursors include tin-containing dopant precursors (such as tetravinyl tin(IV), tetra-ethynyl tin(IV), diethyl tin(II), dimethyl tin(II), and dimethyl(divinyl)tin(IV)), antimony-containing dopant precursors (such as trivinylantimony), tellurium-containing dopant precursors (such as divinyltelluroxide), and iodine-containing dopant precursors (such as iodoethyne, 3-iodopropene, and 3-iodopropyne).

The term “extreme-ultraviolet (EUV) absorbing photoelectron-emissive dopant” may generally represent any atom that absorbs radiation with a wavelength within a range of 124 nanometers (nm) to 10 nm and emits photoelectrons in response. Example EUV-absorbing photoelectron-emissive dopants that may be suitable for use in an underlayer include indium (In), antimony (Sb), tin(Sn), tellurium (Te), and iodine (I).

The term “EUV photolithography process” may generally represent a photolithography process in which a photoresist sensitive to EUV light is exposed to EUV light. The term “EUV photoresist” may generally represent a photoresist material that is sensitive to EUV light. EUV refers to light spanning wavelengths between ˜124 nm to ˜10 nm and photon energies from 10 eV to 124 eV.

The term “functional group” may generally represent an atom or group of atoms in a molecule.

The term “inlet” may generally represent any structure for injecting a gas-phase chemical or plasma into a processing chamber of a processing tool. An inlet may comprise a nozzle or showerhead in various examples.

The term “hydrocarbon precursor” may generally represent any carbon-containing precursor that is polymerizable to form a hydrogen-contributing photosensitive underlayer on a substrate. Example hydrocarbon precursors include unsaturated aliphatic compounds and cyclic aliphatic compounds. For examples where a carbon polymer matrix is to be deposited, example unsaturated aliphatic compounds comprise acetylene, propylene, ethene, and propene. For examples where a silicon carbide or polycarbosilane is to be deposited, a silicon-containing precursor may be used in addition to the carbon-containing precursor. In some examples, a hydrocarbon precursor may comprise a mixture of gases, and further may be mixed with a hydrogen-containing gas.

The term “hydrogen-contributing photosensitive underlayer” may generally represent a material that, when exposed to suitable wavelengths of light, generates labile hydrogen that can migrate to an overlying layer (such as, photoresist layer). Suitable materials for use as a hydrogen-contributing photosensitive underlayer include carbon-based polymers and silicon carbide-based layers.

The term “ion-shielding and radiation-shielding inlet” may generally represent an inlet configured to allow a flow of radical species to pass through while filtering at least some ions and electromagnetic radiation from a plasma. In some examples, an ion-shielding and radiation-shielding inlet may comprise an ion-shielding and radiation-shielding showerhead. The term “showerhead” may generally represent an inlet comprising a plurality of holes configured to introduce a process gas across an area of a substrate.

The term “labile hydrogen” may generally represent hydrogen molecules, hydrogen atoms, or hydrogen ions entrained in a hydrogen-contributing photosensitive underlayer to a photoresist layer. Labile hydrogen may also represent hydrogen atoms, ions and/or radicals that are generated in a hydrogen-contributing photosensitive underlayer to a photoresist layer by EUV light exposure and that can migrate to a photoresist layer.

The term “ligand” may generally represent a functional group that binds to a central metal atom to form a coordination complex.

The term “loose EUV-absorbing photoelectron-emissive dopant” may generally represent EUV-absorbing photoelectron-emissive dopant species in a hydrogen-contributing photosensitive underlayer that are not bonded to atoms. Loose EUV-absorbing photoelectron-emissive dopant may comprise elemental, ionic and/or radical species.

The term “patterning stack” may generally represent a hydrogen-contributing photosensitive underlayer disposed on a substrate, and a photoresist layer disposed on the hydrogen-contributing photosensitive underlayer.

The term “photoresist” may generally represent a light-sensitive material that can be used to transfer a pattern to a substrate through a radiation-induced change in a material property.

The term “photosensitive underlayer” may generally represent a material that undergoes a chemical change when exposed to photons of electromagnetic energy of suitable wavelengths.

The term “plasma” may generally represent an ionized gas comprising positive ions and free electrons. Plasmas may be generated using any suitable method and may include radiofrequency (RF) plasmas, microwave plasmas, and electron beam generated plasmas. A plasma may be used to generate radical species. For example, a hydrogen-containing gas (e.g., H₂, NH₃, N₂H₄) may be introduced into a plasma to generate hydrogen radicals, which are hydrogen atoms with unpaired electrons.

The term “processing chamber” may generally represent an enclosure in which chemical and/or physical processes are performed on substrates. Example chemical and/or physical processes include chemical vapor deposition (CVD), atomic layer deposition (ALD), and etching processes.

The term “processing tool” may generally represent a machine including a processing chamber and other hardware configured to enable processing to be carried out on one or more substrates in the processing chamber.

The term “radical species” may generally represent a chemical species with an unpaired valence shell electron.

The term “remote plasma” may generally represent a plasma that is used to produce chemical species for processing a substrate that is located outside of the plasma.

The term “silicon-containing precursor” may generally represent any silicon-containing material than can be introduced together with a hydrocarbon precursor to deposit a silicon carbide or polycarbosilane. Example silicon-containing precursors for forming siliconcarbides or polycarbosilanes may comprise materials having the general structure:

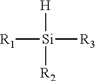

where R₁, R₂ and R₃ may be the same or different substituents, and may include silanes, siloxy groups, amines, halides, hydrogen, or organic groups, such as alkylamines, alkoxy, alkyl, alkenyl, alkynyl and aromatic groups.

Example silicon-containing precursors include polysilanes (H₃Si—(SiH₂)ₙ—SiH₃), where n≥1, such as silane, disilane, trisilane, tetrasilane, and trisilylamine.

In some examples, the silicon-containing precursor is an alkoxysilane. Alkoxysilanes that may be used include the following:
Hₓ—Si—(OR)_{y}, where x=1-3, x+y=4 and each R is a substituted or unsubstituted alkyl, alkenyl, alkynyl or aromatic group; and
Hₓ(RO)_{y}, —Si—Si—(OR)_{y}Hₓ, is a substituted or unsubstituted alkyl, alkenyl, alkynyl or aromatic group.

Examples of silicon-containing precursors include tetraethyl orthosilicate (TEOS), tetramethoxysilane (TMOS), methylsilane, trimethylsilane (3MS), ethylsilane, butasilanes, pentasilanes, octasilanes, heptasilane, hexasilane, cyclobutasilane, cycloheptasilane, cyclohexasilane, cyclooctasilane, cyclopentasilane, 1,4-dioxa-2,3,5,6-tetrasilacyclohexane, diethoxymethylsilane (DEMS), diethoxysilane (DES), dimethoxymethylsilane, dimethoxysilane (DMOS), methyl-diethoxysilane (MDES), methyl-dimethoxysilane (MDMS), t-butoxydisilane, triethoxysilane (TES), and trimethoxysilane (TMS or TriMOS).

In some examples, the silicon-containing precursor may be a siloxane. Example siloxanes include octamethylcyclotetrasiloxane (OMCTS), octamethoxydodecasiloxane (OMODDS), tetramethylcyclotetrasiloxane (TMCTS), triethoxysiloxane (TRIES), and tetraoxymethylcyclotetrasiloxane (TOMCTS).

As noted above, in some examples, the silicon-containing precursor may be an aminosilane, such as bisdiethylaminosilane, diisopropylaminosilane, bis (t-butylamino) silane (BTBAS), di-sec-butylaminosilane, or tris (dimethylamino) silane (3DMAS). Aminosilane precursors include the following: Hₓ—Si—(NR)_{y}, where x=1-3, x+y=4, and R is a substituted or unsubstituted alkyl, alkenyl, alkynyl or aromatic group or hydride group.

In some examples, a halogen-containing silane may be used such that the silane includes at least one hydrogen atom. Such a silane may have a chemical formula of SiXₐH_{y} where y≥1. For example, dichlorosilane (H₂SiCl₂) may be used in some examples.

The term “substrate” may generally represent any structure onto which a patterning stack may be formed. Example substrates include semiconductor wafers.

As described above, photolithography can be used to form a patterned coating on a substrate. In an example process, a photoresist material is applied to a substrate. For example, a wet photoresist can be applied using a spin-on method. A dry photoresist can be applied using a vapor deposition method. Next, the photoresist material is exposed to a pattern of light formed by patterning mask. This exposes some regions of a photoresist to the light while masking other regions from exposure. The exposed regions undergo a chemical reaction that results in structural differences between the exposed regions relative to the unexposed regions. Then, the structural differences between the exposed and unexposed regions are exploited to partially remove the coating. The remaining coating forms a pattern on the substrate.

Semiconductor device manufacturing employs photolithography for many different steps in the fabrication of integrated circuits. The smallest feature size that can be resolved in photolithography can be approximated using the Rayleigh equation, as follows.

$$CD = {k}_{1} \frac{λ}{NA}$$

In this equation, CD is the critical dimension (the width of a feature formed in the photoresist by exposure), k₁ is a parameter related to processing conditions, λ is the wavelength of light used, and NA is the numerical aperture of projection optics. As such, the critical dimension of the feature size is proportional to the wavelength of light used. Thus, smaller feature sizes may be enabled by photolithographic techniques that use shorter wavelengths of light.

Extreme ultraviolet (EUV) lithography is a promising technology for patterning integrated circuits with a line and space pitch <36 nanometers (nm). EUV refers to light spanning wavelengths between ˜124 nm to ˜10 nm and photon energies from 10 eV to 124 eV. In some examples, EUV light may be produced using a laser-driven tin(Sn) plasma light source, for example. Such a light source may produce light with a peak at approximately 13.5 nm and relatively narrow bandwidth. Upon absorption of EUV light, an EUV-sensitive photoresist generates photoelectrons, which drive chemical reactions in the exposed regions of the photoresist. Suitable EUV-sensitive photoresists for λ=13.5 nm may comprise metal-containing photoresists, such as metal oxide photoresists, metal oxide nanoparticle photoresists, and organometallic photoresists (e.g., photoresists comprising Zn, Zr, Sn, Sb, Te, and/or Hf).

However, EUV photoresists may have high sensitivity. Further, optics used in EUV photolithography absorb a portion of incident light. As such, only a relatively small portion of EUV light generated may reach the photoresist. Due to the incident EUV light intensity and high sensitivity, a relatively long exposure time may be required to generate features in the photoresist. Longer exposure times may be associated with lower throughput. Further, longer exposure times also may cause substrate heating. This may lead to outgassing from and/or damage to the substrate. Furthermore, transition regions of the photoresist (regions located between fully exposed regions and fully masked regions) may receive a relatively lower dose (amount of energy per unit area) of EUV light. This may lead to less well-defined features in transition regions.

One method to decrease exposure times of EUV photoresists is to utilize a hydrogen-contributing photosensitive underlayer positioned between a substrate and an EUV photoresist layer. The hydrogen-contributing photosensitive underlayer generates labile hydrogen when exposed to EUV light and/or a post-exposure bake. The labile hydrogen can migrate to the EUV photoresist layer. Labile hydrogen may facilitate water elimination reactions resulting in crosslinking in metal oxide photoresists. For example, in a tin-based metal oxide EUV photoresist, labile hydrogen may inhibit hydroxyl groups from recombining with tin atoms, which allows the tin to form Sn—O—Sn bonds that crosslink tin metaloxy polymer chains. Thus, the labile hydrogen may allow crosslinking to occur with shorter EUV light exposure times.

To further reduce an exposure time, EUV-absorbing photoelectron-emissive dopants can be incorporated into the hydrogen-contributing photosensitive underlayer. An EUV-absorbing photoelectron-emissive dopant may emit EUV photoelectrons upon absorption of EUV light. This may provide additional electrons for driving chemical reactions in the photoresist. Further, photoelectrons generated by the EUV-absorbing photoelectron-emissive dopant also may drive the generation of additional labile hydrogen. Each of these mechanisms may help to reduce photoresist exposure times.

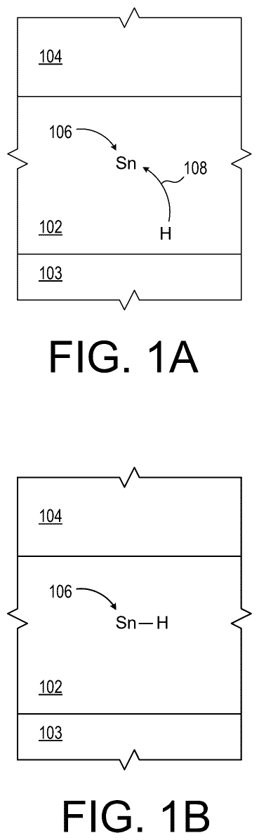

However, some EUV-absorbing photoelectron-emissive elements (e.g., Sn, among others) may readily form hydrides. For example, loose EUV-absorbing photoelectron-emissive dopants that are not bonded to atoms may form hydrides from labile hydrogen. This is illustrated in FIGS. 1A-1B. More particularly, FIG. 1A shows a hydrogen-contributing photosensitive underlayer 102 disposed on a substrate 103. An EUV photoresist layer 104 is disposed on the hydrogen-contributing photosensitive underlayer 102. A loose EUV-absorbing photoelectron-emissive dopant, illustrated as Sn atom 306, is not bonded to atoms in the hydrogen-contributing photosensitive underlayer. Thus, Sn atom 306 may capture one or more labile hydrogen atoms, as indicated at 308. This can form a tin hydride, as shown in FIG. 1B. As such, loose EUV photoelectron-emissive dopants may adversely affect the function of the hydrogen-contributing photosensitive underlayer by capturing labile hydrogen.

Accordingly, examples are disclosed that relate to the use of hydrogen-contributing photosensitive underlayers comprising bonded EUV-absorbing photoelectron-emissive dopants. In one example, a patterning stack formed on a substrate comprises a photoresist layer and a hydrogen-contributing photosensitive underlayer comprising EUV-absorbing photoelectron-emissive dopants that are bonded to atoms in the hydrogen-contributing photosensitive underlayer. The hydrogen-contributing photosensitive underlayer is disposed between the substrate and the photoresist layer. At least some EUV light not absorbed by the photoresist layer may be absorbed by the EUV-absorbing photoelectron-emissive dopants in the hydrogen-contributing photosensitive underlayer. In response, the EUV-absorbing photoelectron-emissive dopants may generate photoelectrons that help drive crosslinking reactions in the photoresist. The photoelectrons also may generate additional labile hydrogen that facilitates crosslinking reactions in the photoresist. Bonding of the EUV-absorbing photoelectron-emissive dopant to atoms in the hydrogen-contributing photosensitive underlayer may reduce the risk of forming dopant hydrides from labile hydrogen in the hydrogen-contributing photosensitive underlayer. Avoiding the generation of dopant hydrides may allow more labile hydrogen and photoelectrons to reach the photoresist layer. As such, the disclosed examples may help improve throughput by lowering photoresist exposure times. The disclosed examples also may help to form well-defined features in transition regions.

A hydrogen-contributing photosensitive underlayer according to the present disclosure may be formed using a dopant precursor and a hydrocarbon precursor. The dopant precursor comprises an EUV-absorbing photoelectron-emissive dopant bonded within a carbon-containing polymerizable molecule. The dopant precursor may react with the hydrocarbon precursor in a polymerization reaction. The polymerization reaction may be facilitated by radical species formed by a plasma. However, plasma ions and/or plasma energy may pose a risk of cleaving the carbon-dopant bond of the dopant precursor. Thus, in some examples, a remote plasma may be used to form the radical species. In such examples, an ion-shielding and radiation-shielding inlet may be used to introduce the radical species into the processing chamber. The ion-shielding and radiation-shielding inlet may help to reduce the risk of high-energy ions and electromagnetic radiation from the plasma damaging the dopant precursor.

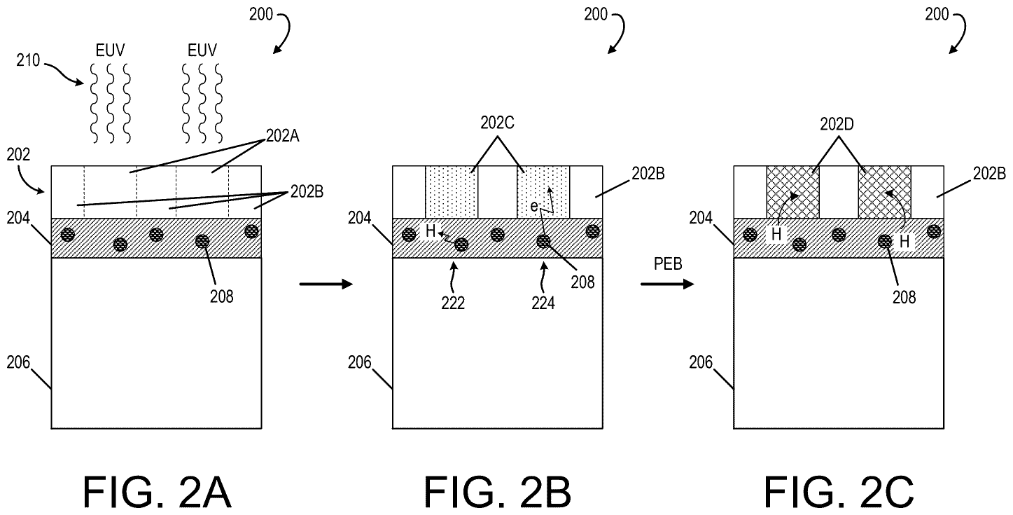

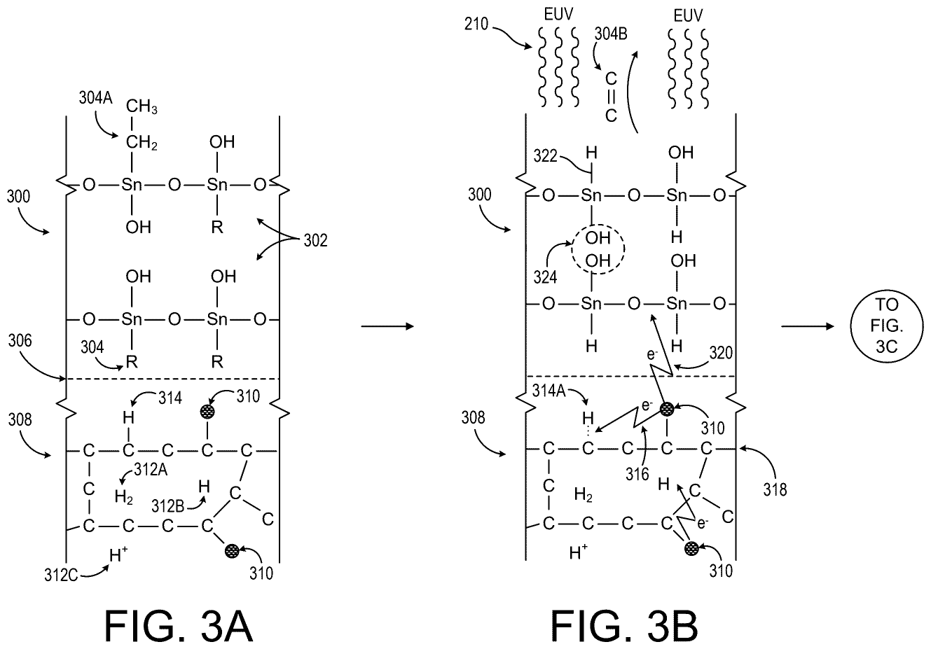

FIGS. 2A-2C illustrate a patterning stack 200 at various stages in an EUV photolithography process. FIGS. 3A-3D illustrate corresponding example chemical reactions for an example tin-based metal oxide photoresist. First referring to FIG. 2A, the patterning stack 200 comprises a photoresist layer 202 and a hydrogen-contributing photosensitive underlayer 204 disposed on a substrate 206. The substrate 206 represents any suitable structure on which the photoresist layer 202 and the hydrogen-contributing photosensitive underlayer 204 may be formed. The hydrogen-contributing photosensitive underlayer 204 comprises EUV-absorbing photoelectron-emissive dopants, illustrated schematically at 208, bonded to carbon atoms.

The photoresist layer 202 may comprise any suitable EUV-sensitive photoresist, including wet photoresists and dry photoresists. A wet photoresist may comprise a photoresist that is applied in a liquid phase. A dry photoresist may comprise a photoresist that is applied by depositing reactive precursors in a vapor phase. In some examples, the photoresist layer 202 may comprise a tin-based metal oxide photoresist that can form Sn—O—Sn crosslinks, as explained in more detail below. The hydrogen-contributing photosensitive underlayer 204 may comprise any suitable material for providing labile hydrogen to photoresist layer 202. For example, the hydrogen-contributing photosensitive underlayer 204 may comprise a carbon-based polymer or silicon carbide-containing material in various examples. As such, in some examples, the EUV-absorbing photoelectron-emissive dopants may be bonded to any suitable atoms (e.g., N, C, Si) within the hydrogen-contributing photosensitive underlayer.

The EUV-absorbing photoelectron-emissive dopants may comprise any suitable atoms having a relatively high absorption cross-section for EUV light. Suitable EUV absorption cross-sections include cross-sections equal to or greater than 1×10⁷ cm²/mol. Example EUV-absorbing photoelectron-emissive dopants that may be suitable for use in a hydrogen-contributing photosensitive underlayer include In, Sn, Sb, Te, and I.

Continuing with FIG. 2A, regions 202A of photoresist layer 202 are exposed to EUV light 210. Regions 202B are masked from exposure by a patterning mask (not shown). Exposure of regions 202A of the photoresist layer 202 and the hydrogen-contributing photosensitive underlayer 204 to EUV light causes the hydrogen-contributing photosensitive underlayer to contribute labile hydrogen to the photoresist layer 202. Referring next to FIG. 2B, the labile hydrogen reacts with the photoresist to form chemically modified photoresist regions 202C. An example reaction of a tin oxide-based photoresist with labile hydrogen is described below with regard to FIG. 3A-3B.

Further, exposure of the EUV-absorbing photoelectron-emissive dopants 208 causes emission of photoelectrons. Some photoelectrons may generate additional labile hydrogen through electron impact-induced detachment (e.g., through bond cleavage), as indicated at 222. Additionally, some photoelectron-emissive dopants may generate photoelectrons, as indicated at 224 that migrate to the photoresist layer 202. Such photoelectrons can augment the photonic dose of the EUV light exposure. Through either or both of these mechanisms, the photoelectrons generated by the EUV-absorbing photoelectron-emissive dopants may help to reduce an exposure time used to form chemically modified photoresist regions 202C.

Next, the photoresist layer 202 comprising the chemically modified photoresist regions 202C is subjected to a post-exposure bake (PEB). The PEB process drives labile hydrogen into the photoresist layer 202. This results in the water elimination reactions and crosslinking of photoresist molecules in the chemically modified photoresist regions 202C. Referring next to FIG. 2C, this results in the formation of crosslinked photoresist regions 202D. A subsequent development process may be used to remove regions 202B of the photoresist film. The development process thus forms a patterned photoresist film comprising crosslinked photoresist regions 202D.

The EUV photolithography process illustrated in FIGS. 2A-2C may be performed using various photoresist chemistries. FIGS. 3A-3D illustrate the process of FIGS. 2A-2C performed on an example tin-based metal oxide EUV photoresist layer 300. First, FIG. 3A shows a molecular structure of an example tin-based metal oxide EUV photoresist layer 300. The tin-based metal oxide EUV photoresist layer 300 comprises tin metaloxy polymer chains 302 (depicted as Sn—O—Sn polymer chains) with functional groups (R) 304 bonded to Sn atoms. Functional groups 304 may comprise any suitable functional group that can undergo a β-hydride elimination reaction. For example, functional group 304A comprises an ethyl group that can undergo β-hydride elimination to form ethene. FIG. 3A also shows an interface 306 between tin-based metal oxide EUV photoresist layer 300 and a hydrogen-contributing photosensitive underlayer 308 comprising a carbon polymer-based structure. Hydrogen-contributing photosensitive underlayer 308 comprises one or more EUV-absorbing photoelectron-emissive dopant atoms 310 bonded to carbon atoms of the carbon polymer-based structure. Hydrogen-contributing photosensitive underlayer 308 further comprises entrained hydrogen, including molecular hydrogen (H₂) 312A, radical hydrogen (H·) 312B, and hydrogen ion (H⁺) 312C. Further, the carbon polymer-based structure comprises H atoms bonded to carbon, such as H 314.

Referring next to FIG. 3B, upon exposure of the structure of FIG. 3A to EUV light 210, labile hydrogen 316 is generated in hydrogen-contributing photosensitive underlayer 308. Labile hydrogen may comprise entrained hydrogen, such as H₂ 312A, H 312B, and H⁺ 312C. Further, photoelectrons generated by EUV-absorbing photoelectron-emissive dopant atoms 310 can generate additional labile hydrogen. For example, as indicated at 316, photoelectrons generated by EUV-absorbing photoelectron-emissive dopant atoms 310 may generate labile hydrogen 314A from hydrogen 314 of a backbone 318 of the carbon-based polymer structure.

Photoelectrons generated by EUV-absorbing photoelectron-emissive dopant atoms 310 also can migrate to the tin-based metal oxide EUV photoresist layer 300, as illustrated by photoelectron 320. Under exposure to EUV light 110 and to photoelectrons from the hydrogen-contributing photosensitive underlayer 308 (e.g., photoelectron 320), bonds between Sn and functional groups 304 are cleaved. As illustrated in FIG. 3B, functional groups 304 are replaced by H. For example, ethyl group 304A undergoes β-hydride elimination to form an ethene 304B and donates a H as illustrated at 322. The chemically modified tin oxide-based EUV photoresist of FIG. 3B may represent chemically modified photoresist regions 202C of FIG. 2B.

In some examples, R functional groups 304 may be relatively bulky. As such, substitution of hydrogen for the R functional groups may bring tin metaloxy polymer chains closer together. This may facilitate cross-linking by water elimination.

As shown in FIG. 3B, water molecules can be eliminated from neighboring hydroxyl groups 324 of tin metaloxy polymer chains to crosslink neighboring chains. FIG. 3C shows the result of water elimination 325 in crosslinked structure 326. As shown in FIG. 3C, heat 328 is applied to help remove water from the crosslinked structure 326. As shown at 330, heat 328 may also help promote migration of labile hydrogen into the photoresist layer. In the depicted example, labile hydrogen may inhibit hydroxyl groups from recombining with tin atoms (e.g. by shifting an equilibrium between Sn—O—Sn linkages and —OH terminated Sn), which in combination with evaporation of water drives the tin to form Sn—O—Sn bonds. As shown in FIG. 3D, crosslinked structure 326 comprises Sn—O—Sn bonds 332 between tin metaloxy polymer chains. Crosslinked structure 326 is an example of crosslinked photoresist regions 202D of FIG. 2C.

As illustrated in FIGS. 2A-2C and FIGS. 3A-3D, the use of an EUV-absorbing photoelectron-emissive dopant in a hydrogen contributing photosensitive underlayer can help reduce exposure times for an EUV photoresist. However, also as mentioned above with regards to FIGS. 1A-1B, the use of a loose EUV-absorbing photoelectron-emissive dopant may lead to the formation of dopant hydrides from labile hydrogen.

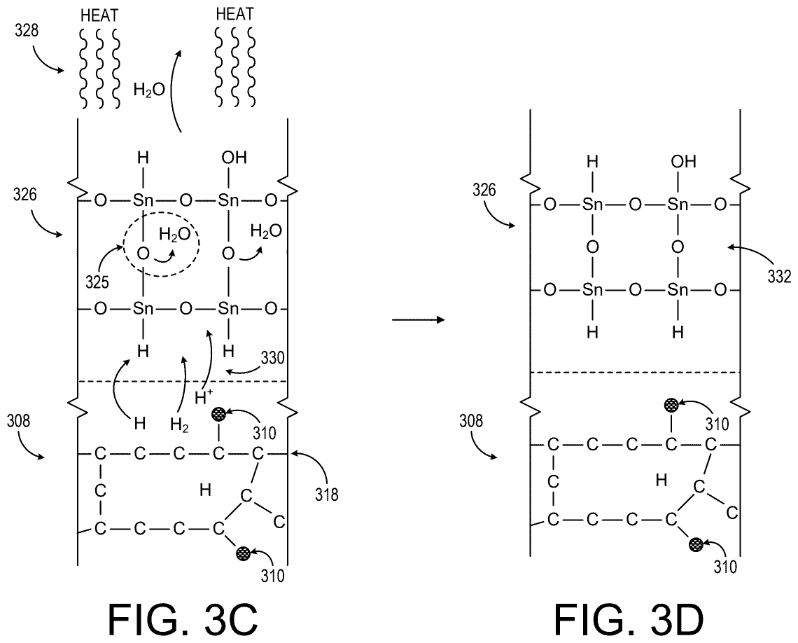

In contrast to FIGS. 1A-1B, FIG. 4 shows a substrate 401 on which a hydrogen-contributing photosensitive underlayer 402 comprising dopants (such as Sn atoms 404) bonded to carbon atoms is disposed. As discussed above, labile hydrogen atoms 406 may comprise H₂, H, or H⁺ entrained in the hydrogen-contributing photosensitive underlayer, or may be generated from carbon-based polymer chains in the hydrogen-contributing photosensitive underlayer. Labile hydrogen atoms 406 may migrate into photoresist layer 408 without being captured by Sn atoms in hydrogen-contributing photosensitive underlayer 402. While the example depicted in FIGS. 1A-1B and 4 uses Sn, any other suitable EUV-absorbing photoelectron-emissive dopant may be used, including In, Sb, Te, and/or I.

A hydrogen-contributing photosensitive underlayer comprising EUV-absorbing photoelectron-emissive dopants that are bonded to atoms may be formed in any suitable manner. In some examples, the hydrogen-contributing photosensitive underlayer may be formed by chemical vapor deposition. In an example process, a hydrocarbon precursor and a dopant precursor as described above may be introduced into a processing chamber comprising a substrate to form a hydrogen-contributing photosensitive underlayer by polymerization. In some examples, the substrate may be heated.

Further, in some examples, the polymerization may be radical-assisted. Any suitable radical source may be used. In some such examples, a plasma may be used to form radical species that initiate polymerization. However, ions and radiation from the plasma may be sufficiently energetic to break ligand-dopant bonds in the dopant precursor. As such, in some examples, the injection of the dopant precursor into a processing chamber may be separated from the injection of radical species by the use of a remote plasma and an ion-shielding and radiation-shielding inlet to introduce radical species created in the plasma to the processing chamber.

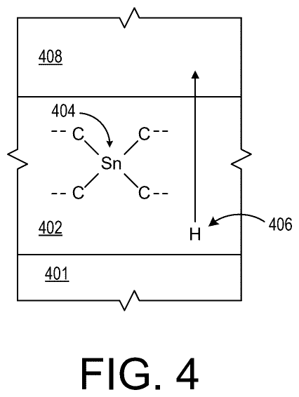

FIG. 5 shows a schematic view of an example processing tool 500 that employs an ion-shielding and radiation-shielding inlet to form a hydrogen-contributing photosensitive underlayer comprising EUV-absorbing photoelectron-emissive dopants. The processing tool 500 comprises a processing chamber 502 and a substrate support 504 within the processing chamber. The substrate support 504 is configured to support a substrate 506 disposed within the processing chamber 502. In some examples, the substrate support 504 comprises a substrate heater 508. The substrate support 504 may comprise a pedestal, a chuck, and/or any other suitable structure.

The processing tool 500 further comprises an ion-shielding and radiation-shielding inlet 510. The ion-shielding and radiation-shielding inlet 510 is configured to introduce precursor gases and radical species into processing chamber 502 while filtering ions and radiation that are generated in a remote plasma generator 530, described in more detail below. In some examples, the ion-shielding and radiation-shielding inlet 510 comprises a showerhead.

The processing tool 500 further comprises flow control hardware 514A-B. The flow control hardware 514A is connected to a dopant precursor source 516, a hydrocarbon precursor source 518, and a hydrogen gas source 520. In the example depicted in FIG. 5, hydrogen gas source 520 can be used as a radical precursor. In some examples, any suitable hydrogen-containing gas (e.g., H₂, NH₃, or N₂H₄) can be used as a radical precursor. Flow control hardware 514B is connected to an inert gas source 522. Flow control hardware 514B is configured to control the flow of a hydrogen-containing gas from hydrogen gas source 520 and/or an inert gas from inert gas source 522 into remote plasma generator 530. Hydrocarbon precursor source 518 may comprise any suitable hydrocarbon that is polymerizable to form a hydrogen-contributing photosensitive underlayer. Example hydrocarbon precursors are described in more detail above.

The dopant precursor source 516 may comprise any suitable dopant precursor that, when reacted with the hydrocarbon precursor, forms a hydrogen-contributing photosensitive underlayer comprising EUV-absorbing photoelectron-emissive dopants bonded to atoms (e.g., carbon atoms of the hydrocarbon precursor). As mentioned above, a dopant precursor may comprise a dopant atom bonded within a carbon-containing polymerizable molecule. Example dopant precursors include tin-containing dopant precursors such as tetravinyl tin(IV), tetra-ethynyl tin(IV), diethyl tin(II), dimethyl tin(II), and dimethyl(divinyl)tin(IV). In some examples, Example dopant precursors further include iodine-containing precursors such as iodoethyne, 3-iodopropene, and 3-iodopropyne. Further examples include precursors comprising In, Sb and Te bonded to a carbon-containing polymerizable molecule. Example carbon-containing polymerizable molecules include vinyl, ethynyl, allyl, propenyl, butenyl, and cyclopropyl ligands, among others discussed above.

The dopant precursor and hydrocarbon precursor are configured to react by polymerization to form a hydrogen-contributing photosensitive underlayer on a substrate. As described above, the hydrogen-contributing photosensitive underlayer comprises a bonded EUV-absorbing photoelectron-emissive dopant. Further, a hydrogen gas from hydrogen source 520, may be introduced.

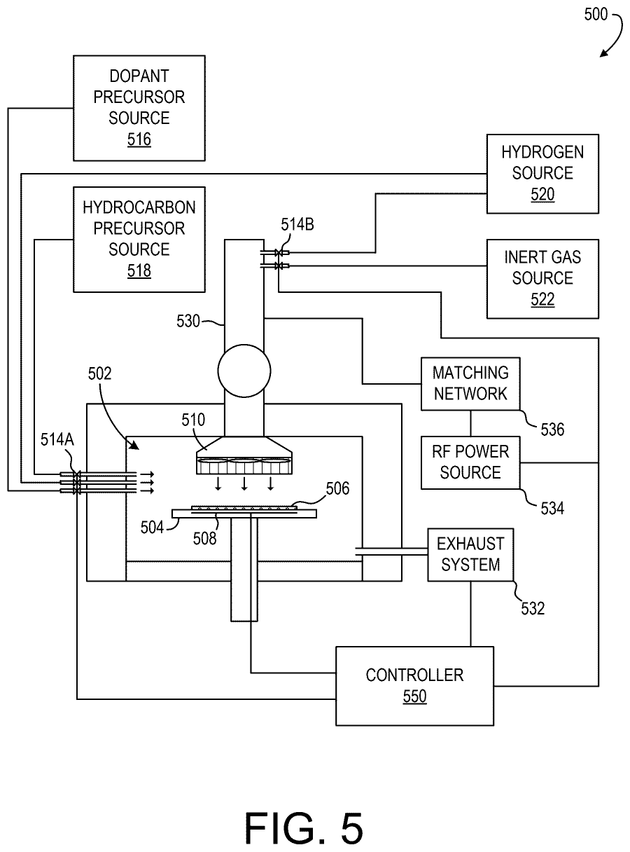

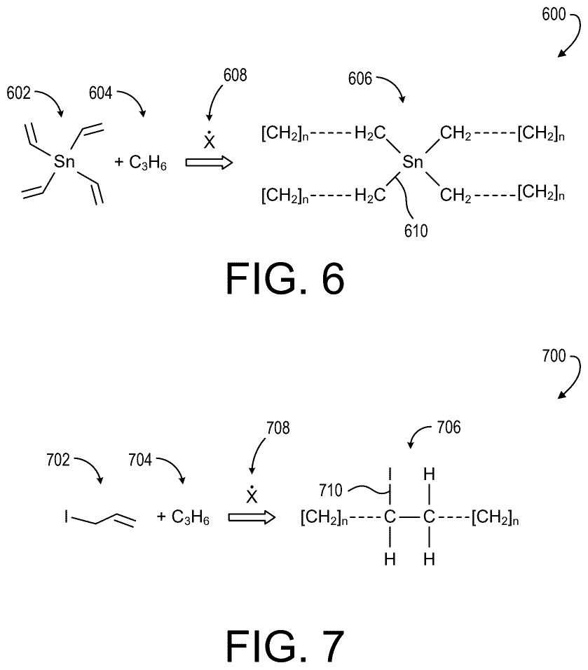

FIGS. 6-7 show example polymerization reactions for forming a hydrogen-contributing photosensitive underlayer comprising bonded EUV-absorbing photoelectron-emissive dopants. First, FIG. 6 illustrates an example polymerization reaction 600 between a dopant precursor 602 and a hydrocarbon precursor 604. Dopant precursor 602 comprises tetravinyl tin(IV). Hydrocarbon precursor 604 comprises propene. Dopant precursor 602 and hydrocarbon precursor 604 react to form a tin-containing polymeric hydrocarbon 606. The polymerization reaction 600 may be facilitated by radical species 608. Radical species 608 may be any suitable radical species. Examples include radicals generated from hydrogen (H₂), deuterium (D₂), ammonia (NH₃), and/or hydrazine (N₂H₄) in a plasma. Radical species 608 may be formed by a plasma, such as a remote plasma. Tin-containing polymeric hydrocarbon 606 comprises Sn—C bonds, such as bond 610. As such, when used as a hydrogen-contributing photosensitive underlayer, the tin atoms in tin-containing polymeric hydrocarbon 606 may help generate EUV photoelectrons without capturing labile hydrogen.

Next, FIG. 7, shows an example a polymerization reaction 700 between a dopant precursor 702 comprising 3-iodopropene and a hydrocarbon precursor 704 comprising propene. Dopant precursor 702 and hydrocarbon precursor 704 react to form an iodine-containing polymeric hydrocarbon 706. The reaction may be facilitated by radical species 708. Examples of radical species include radicals formed from one or more of hydrogen, deuterium, ammonia, or hydrazine in a plasma. As indicated by bond 710, polymeric hydrocarbon 706 comprises iodocarbon (I-C) bonds. As such, when used as a hydrogen-contributing photosensitive underlayer, the iodide (I) atoms in polymeric hydrocarbon 706 may help generate EUV photoelectrons without capturing labile hydrogen. In other examples, any suitable dopant precursor and any suitable hydrocarbon precursor may be used.

Returning to FIG. 5, flow control hardware 514A may be controllable to flow gas from dopant precursor source 516, hydrocarbon precursor source 518, hydrogen gas source 520 into processing chamber 502 to deposit a hydrogen-contributing photosensitive underlayer. Ions and/or radiation from remote plasma generator 530 are filtered by ion-shielding and radiation-shielding inlet 510 prior to introduction of the radical species into processing chamber 502. In the example of FIG. 5, chemicals are introduced from a side of processing chamber 502. Thus, precursor gases are introduced downstream from ion-shielding and radiation-shielding inlet 510. Introducing the dopant precursor downstream from ion-shielding and radiation-shielding inlet 510 may help filter ions and/or high energy radiation to prevent cleavage of bonds between the EUV-absorbing photoelectron-emissive dopant and a carbon-containing polymerizable ligand in the dopant precursor. Introducing hydrogen from hydrogen gas source 520 into the chamber downstream from ion-shielding and radiation-shielding inlet 510 introduces entrained hydrogen into the hydrogen-contributing photosensitive underlayer. In some examples, entrained hydrogen may be introduced into a hydrogen-contributing photosensitive layer via flow control hardware 514B and remote plasma generator 530. In such examples, the connection of hydrogen source 520 to flow control hardware 514A may be omitted.

Remote plasma generator 530 is configured to generate a remote plasma from an inert gas and a radical precursor to generate radical species. In some examples, remote plasma generator 530 may be configured to generate an inductively coupled plasma (ICP). In other examples, remote plasma generator 530 may be configured to generate a capacitively coupled plasma (CCP). In further examples, a microwave plasma may be used. Radical species may flow into the processing chamber through ion-shielding and radiation-shielding inlet 510. Suitable inert gases include He, Ne, Ar, Kr, and N₂. Suitable radical precursors include hydrogen, deuterium, ammonia, and hydrazine. Flow control hardware 514A-B schematically represents any suitable components related to flowing gas into processing chamber 502.

Flow control hardware 514A-B may comprise one or more mass flow controllers and/or valves to control flow rates of gases. In some examples, flow control hardware is controllable to adjust a flow rate ratio between two gases. For example, flow control hardware may be controllable to flow the hydrocarbon precursor and flow the dopant precursor with a gas flow ratio within a range of 2:1 to 100:1 as measured in standard cubic centimeters (sccm).

In some examples, a liquid precursor may be used for dopant precursor source 516 and/or hydrocarbon precursor source 518. In such examples, the liquid precursor may be introduced with a carrier gas as a flow over vapor (FOV). In such examples, flow control hardware 514A may be configured to introduce the liquid precursor to the processing chamber using FOV.

Processing tool 500 further comprises an exhaust system 532. Exhaust system 532 is configured to receive gas outflowing from processing chamber 502. In some examples, exhaust system 532 is configured to actively remove gas from processing chamber 502 and/or apply a partial vacuum. Exhaust system 532 may comprise any suitable hardware, including one or pumps.

As mentioned above, remote plasma generator 530 is configured to form radical species using a plasma. The radical species may facilitate a reaction between the dopant precursor and the hydrocarbon precursor. For example, the radical may initiate polymerization by reacting with an unsaturated carbon-carbon bond and/or opening a cyclic functional group. The plasma may be formed from gas supplied by inert gas source 522. In the depicted example, hydrogen from hydrogen gas source 520 acts as a radical precursor. In other examples, a radical precursor other than hydrogen may be used. As mentioned above, suitable radical precursors include hydrogen, deuterium, ammonia, and hydrazine. Inert gas source 522 may comprise any suitable inert gas such as He, N₂, Ne, Ar, or Kr. In some more specific examples, a H/He plasma is used.

Processing tool 500 further comprises a radiofrequency (RF) power source 534 electrically connected to remote plasma generator 530. Processing tool 500 further may include a matching network 536 for impedance matching of the radiofrequency power source 534. Radiofrequency power source 534 may be configured for any suitable frequency and power. Examples of suitable frequencies include frequencies in a range from 0.3 MHz to 10 GHz. Examples of suitable powers include powers in a range from 10 W to 10 kW. In some examples, radiofrequency power source 534 is configured to operate at a plurality of different frequencies and/or powers.

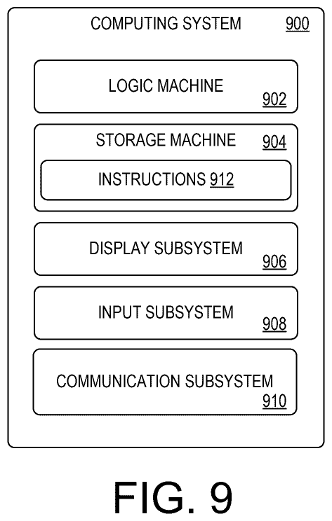

Controller 550 is operatively coupled to substrate heater 508, flow control hardware 514A-B, remote plasma generator 530, exhaust system 532, and radiofrequency power source 534. Controller 550 further may be operatively coupled to any other suitable component of processing tool 500. Controller 550 is configured to control various functions of processing tool 500 to deposit a hydrogen-contributing photosensitive underlayer comprising a bonded EUV-absorbing photoelectron-emissive dopant on substrate 506. For example, controller 550 is configured to operate substrate heater 508 to heat a substrate. Controller 550 is also configured to operate flow control hardware 514A to flow a selected gas or mixture of gases at a selected flow rate into processing chamber 502. Controller 550 is also configured to operate exhaust system 532 to remove gases from processing chamber 502. Controller 550 is further configured to operate flow control hardware 514A-B and exhaust system 532 to maintain a selected pressure within processing chamber 502. Furthermore, controller 550 is configured to operate remote plasma generator 530 and/or radiofrequency power source 534 to form a remote plasma comprising the inert gas and/or hydrogen gas, as well as control any other functions of processing tool 500. Controller 550 may comprise any suitable computing system, examples of which are described below with reference to FIG. 9.

For example, controller 550 may operate flow control hardware 514A to introduce the dopant precursor and the hydrocarbon precursor into processing chamber 502, thereby exposing substrate 506 to the precursor gases. Controller 550 also may operate flow control hardware to introduce the inert gas and/or radical precursor into remote plasma generator 530. Controller 550 further may operate remote plasma generator 530 and/or radiofrequency power source 534 to form a plasma and introduce the radical species into processing chamber 502. Thus, controller 550 may control the introduction of precursor gases and radical species into processing chamber 502 such that the radical species reacts with one or more of the dopant precursor and hydrocarbon precursor to form the hydrogen-contributing photosensitive underlayer on substrate 506.

In some examples, introduction of the dopant precursor alternatively or additionally may be temporally separated from introduction of the radical species. For example, the flow control hardware and remote plasma generator may be configured to alternate exposure of the substrate to precursor gases with exposure to radical species.

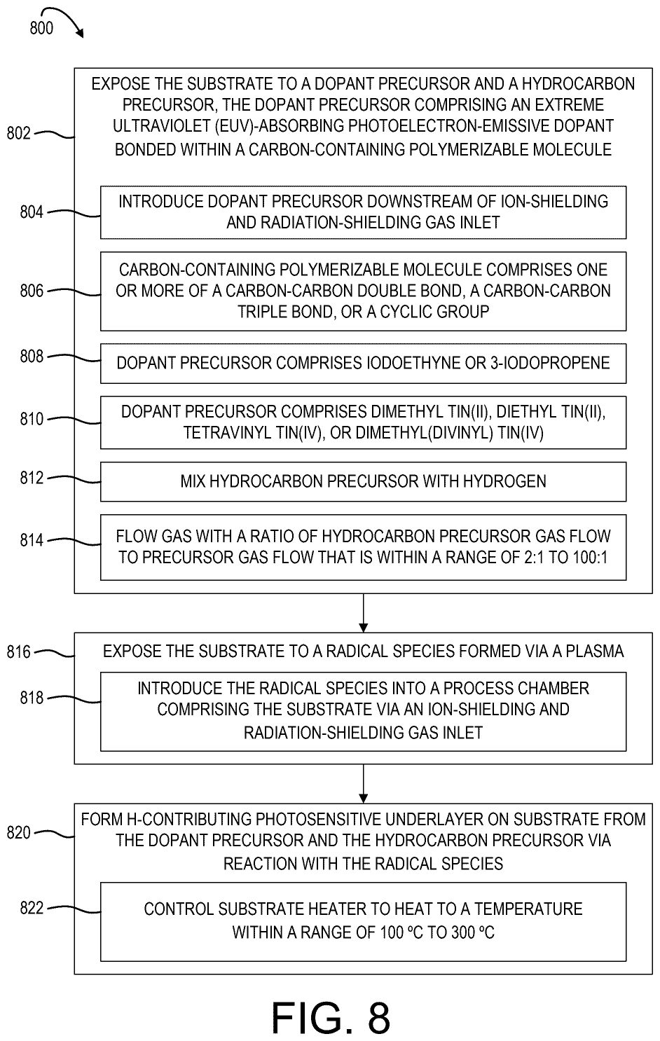

FIG. 8 shows a flow diagram depicting an example method 800 for forming a hydrogen-contributing photosensitive underlayer on a substrate. Processing tool 500 is an example tool for performing method 800. Method 800 comprises, at 802, exposing the substrate to a dopant precursor and a hydrocarbon precursor. The dopant precursor comprises an EUV-absorbing photoelectron-emissive dopant bonded within a carbon-containing polymerizable molecule. In some examples, at 804, the method comprises introducing the dopant precursor downstream from an ion-shielding and radiation-shielding structure of an inlet. In examples where a plasma is used to form radical species, 804 may help to prevent cleavage of the bond between the EUV-absorbing photoelectron-emissive dopant and the carbon-containing polymerizable ligand in examples.

In some examples, the carbon-containing polymerizable molecule comprises one or more of a carbon-carbon double bond, a carbon-carbon triple bond, or a cyclic group, as indicated at 806. For example, the carbon-containing polymerizable molecule may comprise vinyl, ethynyl, allyl, propenyl, butenyl, and/or cyclopropyl ligands. As indicated at 808, in some examples the dopant precursor comprises one or more of iodoethyne or 3-iodopropene. As indicated at 810, in some examples the dopant precursor comprises one or more of dimethyl tin(II), diethyl tin(II), tetravinyl tin(IV) or dimethyl(divinyl)tin(IV).

At 812, in some examples, method 800 comprises mixing the hydrocarbon precursor with hydrogen prior to exposing the substrate to the hydrocarbon precursor. In some examples, at 814, the method comprises flowing gas with a ratio of hydrocarbon precursor gas flow in sccm to dopant precursor gas flow in sccm that is within a range of 2:1 to 100:1.

Continuing, method 800 further comprises, at 816, exposing the substrate to a radical species formed by a plasma. In some examples, at 818, the method comprises introducing the radical species into a processing chamber comprising the substrate through an ion-shielding and radiation-shielding inlet. In such examples, the dopant precursor may be introduced downstream from an ion-shielding and radiation-shielding structure of the ion-shielding and radiation-shielding inlet as indicated at 804.

Continuing, at 820, method 800 further comprises forming a hydrogen contributing photosensitive underlayer on the substrate from the dopant precursor and the hydrocarbon precursor by a reaction of one or more of the dopant precursor and hydrocarbon precursor with the radical species. In some examples, at 822, the method further comprises controlling a substrate heater to heat to a temperature within a range of 100° C. to 300° C.

Thus, the disclosed examples may provide for a hydrogen-contributing photosensitive underlayer comprising bonded EUV-absorbing photoelectron-emissive dopants. When used in a patterning stack, the EUV-absorbing photoelectron-emissive dopants may absorb at least some EUV light not absorbed by an overlying photoresist layer. The EUV-absorbing photoelectron-emissive dopants may generate photoelectrons that help drive crosslinking reactions in the photoresist and/or may generate additional labile hydrogen that facilitates crosslinking reactions in the photoresist. As the EUV-absorbing photoelectron-emissive dopants are bonded to atoms in the hydrogen-contributing photosensitive underlayer, such an underlayer may reduce the risk of forming dopant hydrides from labile hydrogen in the hydrogen-contributing photosensitive underlayer. As such, the disclosed examples may help improve throughput by lowering EUV photoresist exposure times and/or dose. For example, the disclosed examples may achieve a dose-to-size ≤50 mJ/cm² for an EUV photoresist. The disclosed examples also may help to form well-defined features in transition regions. For example, the disclosed examples may be used to form features comprising a pitch ≤36 nm. In some examples, features may be formed comprising a line width roughness of ≤3 nm as measured using after development inspection (ADI). In some examples, features may be formed comprising a local critical dimensional uniformity ≤4 nm as measured using ADI. Further, the disclosed examples may provide an approximately 20% improvement to complex patterning (fidelity) compared to other examples that omit the use of EUV-absorbing photoelectron-emissive dopants bonded to atoms in a hydrogen-contributing photoresist underlayer. While disclosed in the context of EUV photoresists, the disclosed examples also may be used with any other suitable photoresist, including photoresists that absorb in spectra other than EUV wavelengths.

In some embodiments, the methods and processes described herein may be tied to a computing system of one or more computing devices. In particular, such methods and processes may be implemented as a computer-application program or service, an application-programming interface (API), a library, and/or other computer-program product.

FIG. 9 schematically shows a non-limiting embodiment of a computing system 900 that can enact one or more of the methods and processes described above. Computing system 900 is shown in simplified form. Computing system 900 may take the form of one or more personal computers, workstations, computers integrated with wafer processing tools, and/or network accessible server computers.

Computing system 900 includes a logic machine 902 and a storage machine 904. Computing system 900 may optionally include a display subsystem 906, input subsystem 908, communication subsystem 910, and/or other components not shown in FIG. 9. Controller 550 is an example of computing system 900.

Logic machine 902 includes one or more physical devices configured to execute instructions. For example, the logic machine may be configured to execute instructions that are part of one or more applications, services, programs, routines, libraries, objects, components, data structures, or other logical constructs. Such instructions may be implemented to perform a task, implement a data type, transform the state of one or more components, achieve a technical effect, or otherwise arrive at a desired result.

The logic machine may include one or more processors configured to execute software instructions. Additionally or alternatively, the logic machine may include one or more hardware or firmware logic machines configured to execute hardware or firmware instructions. Processors of the logic machine may be single-core or multi-core, and the instructions executed thereon may be configured for sequential, parallel, and/or distributed processing. Individual components of the logic machine optionally may be distributed among two or more separate devices, which may be remotely located and/or configured for coordinated processing. Aspects of the logic machine may be virtualized and executed by remotely accessible, networked computing devices configured in a cloud-computing configuration.

Storage machine 904 includes one or more physical devices configured to hold instructions 912 executable by the logic machine to implement the methods and processes described herein. When such methods and processes are implemented, the state of storage machine 904 may be transformed—e.g., to hold different data.

Storage machine 904 may include removable and/or built-in devices. Storage machine 904 may include optical memory (e.g., CD, DVD, HD-DVD, Blu-Ray Disc, etc.), semiconductor memory (e.g., RAM, EPROM, EEPROM, etc.), and/or magnetic memory (e.g., hard-disk drive, floppy-disk drive, tape drive, MRAM, etc.), among others. Storage machine 904 may include volatile, nonvolatile, dynamic, static, read/write, read-only, random-access, sequential-access, location-addressable, file-addressable, and/or content-addressable devices.

It will be appreciated that storage machine 904 includes one or more physical devices. However, aspects of the instructions described herein alternatively may be propagated by a communication medium (e.g., an electromagnetic signal, an optical signal, etc.) that is not held by a physical device for a finite duration.

Aspects of logic machine 902 and storage machine 904 may be integrated together into one or more hardware-logic components. Such hardware-logic components may include field-programmable gate arrays (FPGAs), program- and application-specific integrated circuits (PASIC/ASICs), program- and application-specific standard products (PSSP/ASSPs), system-on-a-chip (SOC), and complex programmable logic devices (CPLDs), for example.

When included, display subsystem 906 may be used to present a visual representation of data held by storage machine 904. This visual representation may take the form of a graphical user interface (GUI). As the herein described methods and processes change the data held by the storage machine, and thus transform the state of the storage machine, the state of display subsystem 906 may likewise be transformed to visually represent changes in the underlying data. Display subsystem 906 may include one or more display devices utilizing virtually any type of technology. Such display devices may be combined with logic machine 902 and/or storage machine 904 in a shared enclosure, or such display devices may be peripheral display devices.

When included, input subsystem 908 may comprise or interface with one or more user-input devices such as a keyboard, mouse, or touch screen. In some embodiments, the input subsystem may comprise or interface with selected natural user input (NUI) componentry. Such componentry may be integrated or peripheral, and the transduction and/or processing of input actions may be handled on- or off-board. Example NUI componentry may include a microphone for speech and/or voice recognition, and an infrared, color, stereoscopic, and/or depth camera for machine vision and/or gesture recognition.

When included, communication subsystem 910 may be configured to communicatively couple computing system 900 with one or more other computing devices. Communication subsystem 910 may include wired and/or wireless communication devices compatible with one or more different communication protocols. As non-limiting examples, the communication subsystem may be configured for communication using a wireless telephone network, or a wired or wireless local- or wide-area network. In some embodiments, the communication subsystem may allow computing system 900 to send and/or receive messages to and/or from other devices through a network such as the Internet.

It will be understood that the configurations and/or approaches described herein are exemplary in nature, and that these specific embodiments or examples are not to be considered in a limiting sense, because numerous variations are possible. The specific routines or methods described herein may represent one or more of any number of processing strategies. As such, various acts illustrated and/or described may be performed in the sequence illustrated and/or described, in other sequences, in parallel, or omitted. Likewise, the order of the above-described processes may be changed.

The subject matter of the present disclosure includes all novel and non-obvious combinations and sub-combinations of the various processes, systems and configurations, and other features, functions, acts, and/or properties disclosed herein, as well as any and all equivalents thereof.

1. A method of forming a photosensitive underlayer on a substrate, the method comprising:
exposing the substrate to a dopant precursor and a hydrocarbon precursor, the dopant precursor comprising an extreme ultraviolet (EUV)-absorbing photoelectron-emissive dopant bonded within a carbon-containing polymerizable molecule;
exposing the substrate to a radical species; and
forming a hydrogen-contributing photosensitive underlayer on the substrate from the dopant precursor and the hydrocarbon precursor by reaction of the dopant precursor and the hydrocarbon precursor with the radical species.

2. The method of claim 1, wherein exposing the substrate to the radical species comprises introducing the radical species from a remote plasma into a processing chamber comprising the substrate through an ion-shielding and radiation-shielding inlet.

3. The method of claim 2, wherein the dopant precursor is introduced downstream of an ion-shielding and radiation-shielding structure of the ion-shielding and radiation-shielding inlet.

4. The method of claim 1, wherein the carbon-containing polymerizable molecule comprises one or more of a carbon-carbon double bond, a carbon-carbon triple bond, or a cyclic group.

5. The method of claim 1, further comprising mixing the hydrocarbon precursor with a hydrogen-containing gas before exposing the substrate to the hydrocarbon precursor.

6. The method of claim 1, wherein the dopant precursor comprises an iodine-containing dopant precursor.

7. The method of claim 6, wherein the iodine-containing dopant precursor comprises one or more of iodoethyne or 3-iodopropene.

8. The method of claim 1, wherein the dopant precursor comprises a tin-containing dopant precursor.

9. The method of claim 8, wherein the tin-containing dopant precursor comprises one or more of dimethyl tin(II), diethyl tin(II), tetravinyl tin(IV) or dimethyl(divinyl)tin(IV).

10. The method of claim 1, wherein a ratio of hydrocarbon precursor gas flow in standard cubic centimeters per minute (sccm) to dopant precursor gas flow in sccm is within a range of 2:1 to 100:1.

11. (canceled)

12. A patterning stack disposed on a substrate, the patterning stack comprising:
a photoresist layer; and
a hydrogen-contributing photosensitive underlayer disposed between the photoresist layer and the substrate, the hydrogen-contributing photosensitive underlayer comprising extreme ultraviolet (EUV)-absorbing photoelectron-emissive dopant bonded to atoms in the hydrogen-contributing photosensitive underlayer.

13. The patterning stack of claim 12, wherein the hydrogen-contributing photosensitive underlayer comprises silicon carbide.

14. The patterning stack of claim 12, wherein the hydrogen-contributing photosensitive underlayer comprises a carbon-based polymer.

15. The patterning stack of claim 12, wherein the EUV-absorbing photoelectron-emissive dopant comprises one or more of In, Sn, Sb, Te, or I.

16. The patterning stack of claim 12, wherein the photoresist layer comprises an extreme ultraviolet (EUV) photoresist.

17. (canceled)

18. A processing tool comprising:
a processing chamber;
a plasma generator;
a radiofrequency power source configured to provide radiofrequency power to the plasma generator;
flow control hardware configured to control gas flow into the processing chamber and into the plasma generator;
a logic subsystem; and
a storage subsystem comprising instructions executable by the logic subsystem to:
control the flow control hardware to introduce a dopant precursor and a hydrocarbon precursor into the processing chamber, the dopant precursor comprising an extreme ultraviolet (EUV)-absorbing photoelectron-emissive dopant bonded within a carbon-containing polymerizable molecule,
control the flow control hardware to introduce an inert gas into the plasma generator;
control the radiofrequency power source to form a plasma in the plasma generator; and
control the flow control hardware to introduce a radical species precursor into the plasma generator.

19. The processing tool of claim 18, further comprising a dopant precursor gas source, wherein the dopant precursor gas source comprises one or more of an iodine-containing dopant or a tin-containing dopant.

20. The processing tool of claim 18, further comprising an ion-shielding and radiation-shielding inlet connecting the plasma generator and the processing chamber.

21. The processing tool of claim 18, wherein the instructions are executable to control the flow control hardware to flow the hydrocarbon precursor and flow the dopant precursor with a gas flow ratio within a range of 2 sccm:1 sccm to 10 sccm:1 sccm.

22. The processing tool of claim 18, further comprising a substrate heater and wherein the instructions are further executable to control the substrate heater to heat to a temperature within a range of 100° C. to 300° C.
